(19) United States
(12) Patent Application Publication
(10) Pub. No.: US 2025/0112185 A1
(43) Pub. Date: Apr. 3, 2025

(54) SUPERHYDROPHOBIC SURFACES FOR LIQUID CONTAINMENT IN SELF-ALIGNMENT ASSISTED ASSEMBLY OF INTEGRATED CIRCUIT DIE STACKS

(71) Applicant: Intel Corporation, Santa Clara, CA (US)

(72) Inventors: Thomas Sounart, Chandler, AZ (US); Michael Baker, Gilbert, AZ (US); Seyed Hadi Zandavi, Pheonix, AZ (US); Yi Shi, Chandler, AZ (US); Feras Eid, Chandler, AZ (US)

(73) Assignee: Intel Corporation, Santa Clara, CA (US)

(21) Appl. No.: 18/374,515

(22) Filed: Sep. 28, 2023

(51) Int. Cl. H01L 23/00

(52) U.S. Cl. CPC H01L 24/08; H01L 24/80; H01L 24/05; H01L 24/16; H01L 24/32; H01L 24/73; H01L 24/95; H01L 2224/0557; H01L 2224/05647; H01L 2224/08145; H01L 2224/08225; H01L 2224/16225; H01L 2224/32225; H01L 2224/73204; H01L 2224/80143; H01L 2224/80365; H01L 2224/80385; H01L 2224/80447; H01L 2224/80896; H01L 2224/95146

(57) ABSTRACT

Hybrid bonded die stacks, related apparatuses, systems, and methods of fabrication are disclosed. One or both of an integrated circuit (IC) die hybrid bonding region and a base substrate hybrid bonding region are surrounded by superhydrophobic structures that have a contact angle not less than 150 degrees. The hybrid bonding regions are brought together with a liquid droplet therebetween, and capillary forces cause the IC die to self-align. The liquid droplet is pinned to the hybrid bonding regions by the superhydrophobic structures. A hybrid bond is formed by evaporating the droplet and a subsequent anneal.

### BACKGROUND

The integrated circuit industry is continually striving to produce ever faster, smaller, and more efficient integrated circuit devices, packages, and systems for use in various electronic products. Current die stacks can be formed using solder to solder bump attachment techniques. For example, on two separate dies, solder bumps may be deposited on copper pillars. The solder bumps may then be brought into contact to join the dies, and underfill material may be formed between the solder bonds and copper pillars. Such processes disadvantageously necessitate a large distance between the bonded dies and limits the ability to scale to lower pitches.

Alternatively, hybrid bonds may be formed between corresponding metallic bond pads on the two dies, with the metallic bond pads interspersed among dielectric material (e.g., an oxide). Prior to bonding, the surface of each die may be controlled to promote bonding by providing a recess of the metallic bond pads relative to the dielectric material, having the dielectric material be planar and relatively smooth, and others. The dies, having mirror image bond pads, are then brought together using liquid droplet alignment such that corresponding metallic bond pads and corresponding dielectric material surfaces of the two dies interface with one another after evaporation of the liquid droplet. At room temperature, the dielectric materials adhere sufficiently to one another (due to Van der Waals forces) to maintain a bond. A high temperature anneal is then performed to bond the corresponding metallic bond pads, and to improve the dielectric material bond. Such processes reduce the distance between the bonded dies, reduce pitches between the metal bonds, and offer other advantages. For example, solder bump techniques may be limited to pitches of about 30 μm while hybrid bonding can attain less than 10 μm and even less than 1 μm pitches.

However, difficulties in forming 3D die stacks using hybrid bonding techniques persist. For example, ensuring the liquid droplet remains pinned (e.g., only on the hybrid bonding region) is challenging particularly for all conditions and die sizes. It is with respect to these and other considerations that the present improvements have been needed. Such improvements may become critical as the desire to provide improved integrated circuit devices, packages, and systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 provides a flow diagram illustrating an example process for fabricating integrated circuit (IC) structures inclusive of 3D die stacks with hybrid bonding regions within superhydrophobic containment features;

FIGS. 2, 3, 4, 5 and 6 are illustrations of IC structures having different structural implementations of superhydrophobic containment features being prepared for self-alignment bonding;

FIG. 7 is an illustration of an IC structures having second order superhydrophobic containment features;

FIG. 8 is an illustration of an IC structure having a hydrophobic material layer on the superhydrophobic containment features;

FIGS. 9 and 10 are illustrations of IC structures having superhydrophobic containment formed in a substrate material;

FIGS. 11, 12, 13, and 14 are illustrations of IC structures as superhydrophobic containment features are fabricated;

FIGS. 15, 16, 17, and 18 are illustrations of hybrid bonding of IC dies to a base substrate;

FIG. 19 illustrates an example microelectronic device assembly including a 3D die stack having a hybrid bond with a superhydrophobic surface around an outer perimeter of the hybrid bond;

FIG. 20 illustrates an example microelectronic device system including a 3D die stack having a hybrid bond with a superhydrophobic surface around an outer perimeter of the hybrid bond; and

FIG. 21 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direction contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Integrated circuit structures, 3D die stack structures, devices, apparatuses, systems, and methods are described herein related to superhydrophobic surfaces to surround hybrid bonding regions during self-alignment assisted assembly such that the superhydrophobic surfaces pin or contain a liquid droplet during hybrid bonding alignment.

As described above, hybrid bonding techniques offer advantages in the assembly of 3D die stacks. As used herein, the term multi-level 3D die stack indicates a stack of devices or structures having at least partially vertically aligned layers such that each layer or level of the 3D die stack may employ one or more IC dies each. The term layer or level of a 3D die stack indicates a horizontal portion of the 3D die stack that includes only one depth of device within the horizontal portion (e.g., each layer or level may have any number of IC dies in the horizontal plane). The term multi-level 3D die stack indicates a die stack having multiple levels such as two or more levels over a base substrate. The term IC die includes any monolithic integrated device that provides electrical, compute, memory, or similar functionality. IC dies include chiplets, chiplet dies, memory dies, processor dies, routing dies, and so on. Herein, the terms chiplet and IC die are used interchangeably. An IC die may be passive such that it only includes electrical routing, or it may be active such that it includes electrical devices such as transistors, capacitors, etc. The term base substrate, base wafer, or base die indicates a substrate having active or passive electrical features. In contrast, the term structural substrate, structural wafer, or structural die indicates a substrate absent any active or passive electrical features. For example, a structural substrate may be a monolithic material such as silicon, or other base material that provides structural support and heat removal.

In the context of hybrid bonding of IC dies, faster throughput may be attained during die-to-wafer hybrid bonding (D2 W HB) using self-alignment assisted assembly (SA3). In SA3 process flows, a liquid droplet is dispensed on the bonding area on either the top chiplet die or the base wafer to be bonded. A bonder is then used to pick and place the chiplet die onto the base wafer at coarse alignment (e.g., ˜25-50 μm), such that the water droplet is sandwiched in the bonding area between the chiplet and the base wafer. Capillary forces cause the chiplet to self-align to its desired bonding location on the wafer with high positional accuracy (e.g., <200 nm) due to containment features (e.g., SA3 features) designed into the chiplet die and base wafer that confine the droplet to the bonding area with high precision. Such containment features may be characterized as alignment features, SA3 features, or the like. The liquid then evaporates, leaving the chiplet bonded to the base wafer at room temperature due to attractive surface forces (e.g., Van der Waals forces) between the dielectric regions on the chiplet and base wafer. An annealing step is then carried out to form and/or strengthen bonds between the metal pads (e.g., copper pads) dispersed between the dielectric regions, forming electrical interconnects between the chiplet and base wafer. The annealing step may also strengthen the bond between the dielectric regions.

Containment of the liquid droplet is an ongoing challenge. The techniques and structures discussed herein deploy superhydrophobic surfaces adjacent the hybrid bonding region to contain or pin the liquid droplet during self-alignment assisted assembly. Notably, liquid droplet pinning is enhanced by increasing the liquid contact angle (CA) at the liquid droplet boundary (e.g., at the boundary between the hybrid bonding region and adjacent containment region). The techniques and structures discussed herein attain the highest CA possible by deploying superhydrophobic surfaces. As used herein, the term superhydrophobicity is defined as a containment feature or region having a CA of not less than 150 degrees. In some embodiments, superhydrophobic surfaces are attained using micro-rod or micro-needle arrays (e.g., rods or needles having a diameter on the order of 10s of μm) or nano-rod or nano-needle arrays (e.g., rods needles having a diameter on the order of 10s of nm). The terms rods or needles indicate features having a height to width aspect ratio of not less than one. The term needle indicates a feature having an end that substantially tapers to point while rods are features with a flat top or a rounded top. rods and needles are used interchangeably.

In some embodiments, the superhydrophobic surfaces that include hierarchical structures have been demonstrated to yield CA of not less than 170 degrees. As used herein, the term hierarchical structure with respect to rods or needles indicates rods or needles that further include at least second level rods or needles or other features that extend from the primary rods or needles, and can include higher level features such as third level rods or needles that extend from the second level rods or needles, and so on. Notably, the term hierarchical structure may be applied to other structures as discussed herein, and is not limited to use of rods or needles. For example, the primary rods or needles may have an aspect ratio of not less than one and a particular cross-sectional width (e.g., on the order of 10s of microns or 10s of nanometers) while the secondary features extend from the surfaces of the primary rods or needles. These secondary features may also have an aspect ratio of not less than one and a particular cross-sectional width that is a fraction of the cross-sectional width of the primary rods or needles (e.g., not more than 50% of the cross-sectional width of the primary rods or needles).

In some embodiments, superhydrophobic surfaces are attained using random shapes inclusive of highly roughened surfaces, which can include secondary structures. In some embodiments, the rods or needles may be longer in a planar dimension, such that they are similar to plates, and such that the plates may have tapered or rounded tops. In such contexts, the plates may have secondary structures from roughening or secondary plate or nano-rod growth from the surfaces of the plates such as sidewalls of the plates. Notably, the superhydrophobic surfaces may have any shape and structure that has locally hydrophobic material surfaces and gaps between the hydrophobic material surfaces shapes that create very low surface area contact with the alignment liquid relative to the planar area of the hybrid bonding regions. In some embodiments, the contact surface area of the hydrophobic material surfaces shapes is not more than 50% of the total area. In some embodiments, the contact surface area of the hydrophobic material surfaces shapes is not more than 10% of the total area. The term contact surface area indicates an area of the structure itself while the term total surface area is the contact surface area plus the areas of the gaps between the contact surface area. In some embodiments, such areas are taken in a plane substantially coplanar with a hybrid bond plane.

As discussed herein, superhydrophobic surfaces are deployed that may be fabricated using complementary metal-oxide semiconductor (CMOS) compatible processes The superhydrophobic surfaces provide a droplet pinning boundary at the edge of the hybrid bonding regions (of a base substrate, a chiplet, or both) to ensure reliable droplet pinning for all die sizes and process flows. In addition, such superhydrophobic surfaces may include a hydrophobic material coating on the rods or needles.

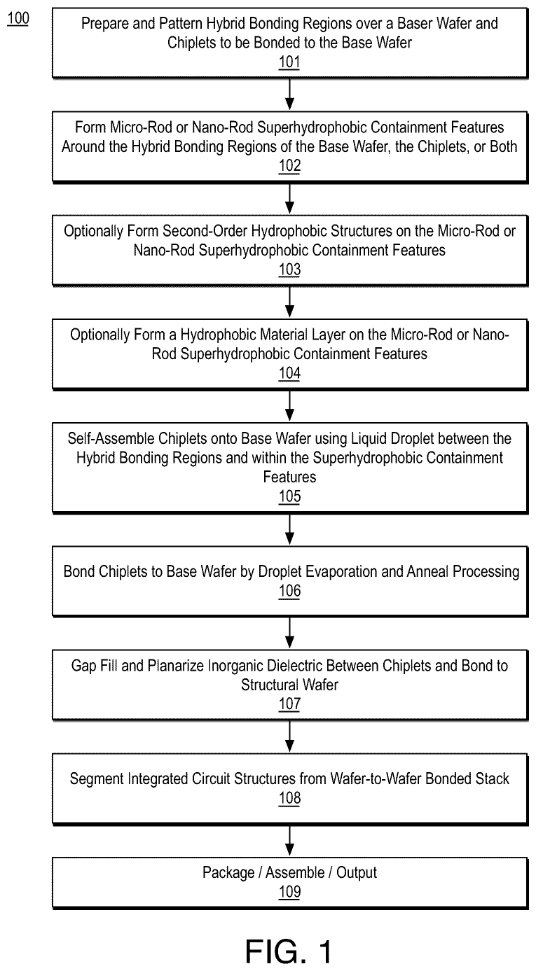

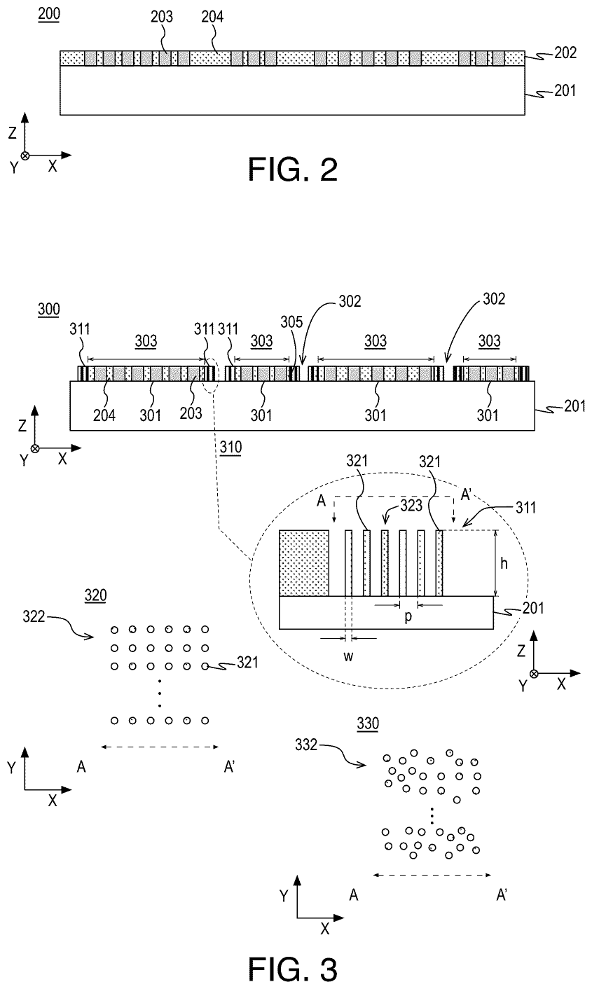

FIG. 1 provides a flow diagram illustrating an example process 100 for fabricating integrated circuit (IC) structures inclusive of 3D die stacks with hybrid bonding regions within superhydrophobic containment features, arranged in accordance with at least some implementations of the present disclosure. For example, process 100 may be implemented to fabricate IC structure 1800 or assembly structures including IC structure 1800 such as assembly structure 1900, or any other structure discussed herein. In the illustrated embodiment, process 100 includes one or more operations as illustrated by operations 101-109. However, embodiments herein may include additional operations, certain operations being omitted, or operations being performed out of the order provided. FIGS. 2-19 illustrate structures and components as the methods of process 100 are practiced.

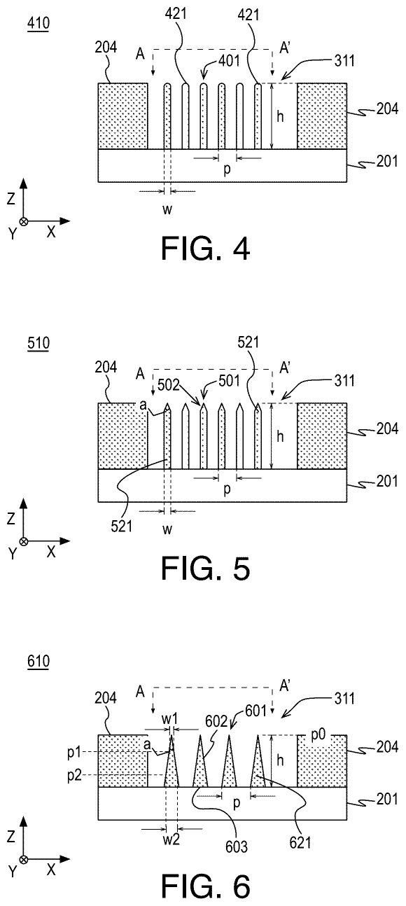

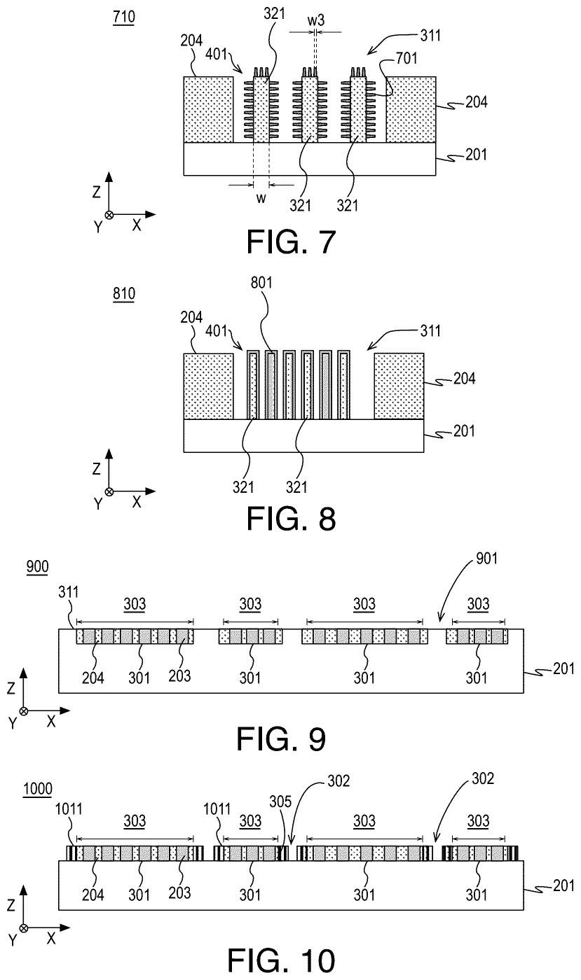

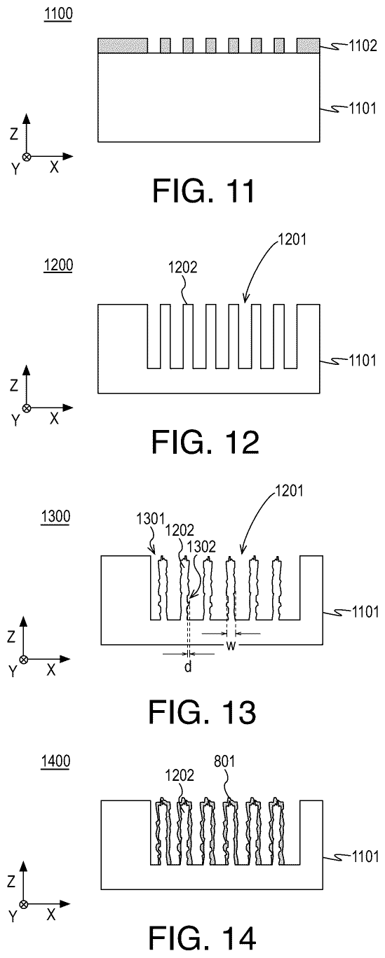

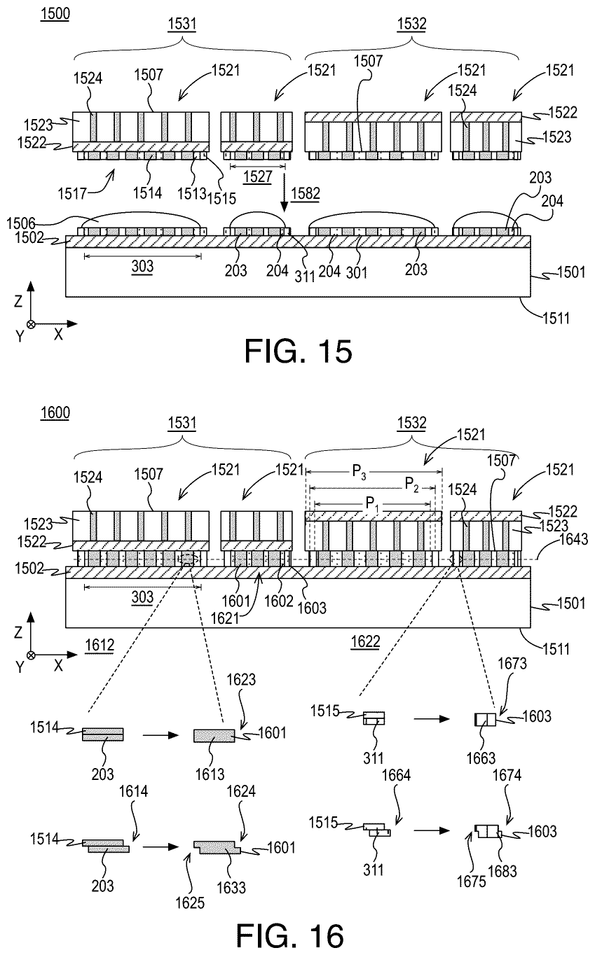

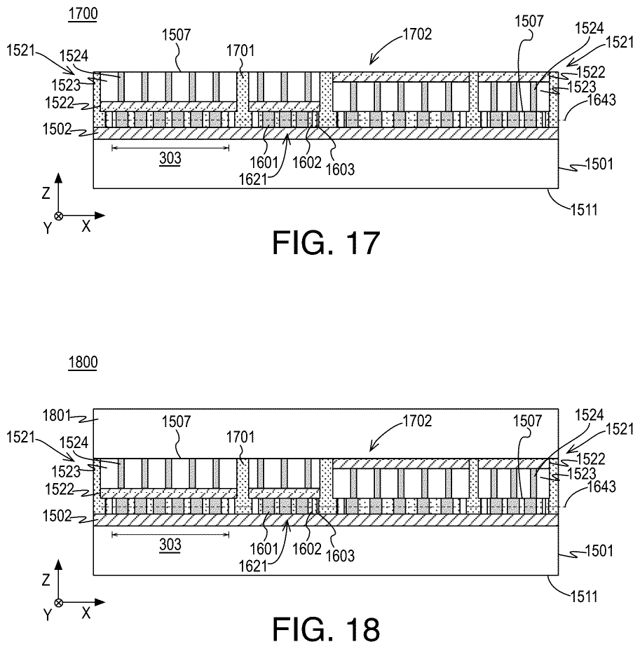

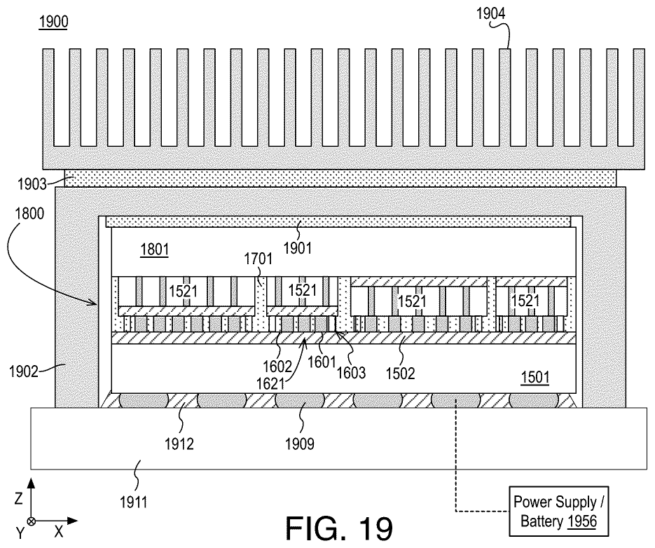

FIGS. 2, 3, 4, 5 and 6 are illustrations of integrated circuit (IC) structures having different structural implementations of superhydrophobic containment features being prepared for self-alignment bonding, arranged in accordance with at least some implementations of the present disclosure. FIG. 7 is an illustration of an integrated circuit (IC) structures having second order superhydrophobic containment features, arranged in accordance with at least some implementations of the present disclosure. FIG. 8 is an illustration of an integrated circuit (IC) structure having a hydrophobic material layer on the superhydrophobic containment features, arranged in accordance with at least some implementations of the present disclosure. FIG. 9 and are illustrations of integrated circuit (IC) structures having superhydrophobic containment formed in a substrate material, arranged in accordance with at least some implementations of the present disclosure. FIGS. 11, 12, 13, and 14 are illustrations of integrated circuit (IC) structures as superhydrophobic containment features are fabricated, arranged in accordance with at least some implementations of the present disclosure. FIGS. 15, 16, 17, and 18 are illustrations of hybrid bonding of IC dies to a base substrate, arranged in accordance with at least some implementations of the present disclosure. FIG. 19 is an illustration of an assembly structure similar to the IC structure of FIG. 18 after packaging and deployment of heat removal solutions, arranged in accordance with at least some implementations of the present disclosure.

Process 100 begins at operation 101, where hybrid bonding regions or areas are prepared and/or patterned. The hybrid bonding regions may be formed on or over a base substrate and/or on or over an IC die to be attached to a base substrate. Processing continues at operation 102, where the hybrid bonding regions are surrounded by superhydrophobic containment features that surround the hybrid bonding regions. In some embodiments, the superhydrophobic containment features that provide a hydrophobic structure having a lateral contact surface area that is not more than 50% of a total lateral surface area of the hydrophobic structure. In some embodiments, the superhydrophobic containment features include rods or needles that surround the hybrid bonding regions and have an axis that is substantially orthogonal to a plane defined by the hybrid bonding regions. The hybrid bonding regions may thereby provide hydrophilic structures and the superhydrophobic containment features are to contain a liquid droplet (applied at operation 105) within the hydrophilic structures for alignment purposes. Operations 101 and 102 are discussed in the following with respect to FIGS. 2, 3, 4, 5, 6, 9, 10, 11, and 12.

Processing continues at operation 103, where optional second order hydrophobic structures are formed on the primary hydrophobic structures. As discussed, such second order hydrophobic structures may be structures that are formed on or from the primary hydrophobic structures to further enhance the superhydrophobic containment features. In some embodiments, the second order hydrophobic structures are rods or needles that extend from primary rods or needles (e.g., first order hydrophobic structures). In some embodiments, the second order hydrophobic structures are a surface roughness applied to the primary rods or needles. Operation 103 is discussed in the following with respect to FIGS. 7 and 13.

Processing continues at operation 104, where an optional hydrophobic material layer is formed on superhydrophobic structures (e.g., rods or needles) and the second order hydrophobic structures (if used). The hydrophobic material layer may be any suitable material or materials that enhance containment of the liquid droplet. For example, the hydrophobic material layer may be any suitable chemical coating that provides a hydrophobic boundary with a large contact angle (e.g. >90 degrees even absent the rods or needles). In some embodiments, the hydrophobic material layer is or includes a self-assembled monolayer (SAM) material such as an alkyl or fluoroalkyl silane (e.g., ODS, FDTS), a thiol (e.g., hexadecane thiol), a phosphonic acid (e.g., octadecyl or perfluorooctane phosphonic acid), or an alkanoic acid (e.g., heptadecanoic acid). In some embodiments, non-SAM based materials or films may be used. In some embodiments, the hydrophobic material layer is or includes a thin polymer film such as a siloxane (e.g., PDMS and derivatives, HMDSO), a silazane (HMDS), a polyolefin (e.g., PP), or a fluorinated polymer (e.g., PTFE, PFPE, PFDA, C4F8 plasma polymerized films, etc.). Other hydrophobic materials may be used. Operation 104 is discussed in the following with respect to FIGS. 8 and 14.

FIG. 2 is an illustration of a cross-sectional side view of an IC structure 200 being prepared for self-alignment bonding. As shown, IC structure 200 includes a substrate 201 and a hybrid bonding layer 202 formed on substrate 201. Substrate 201 may be a base wafer (as discussed further herein below) or a structural wafer or panel or the like on which IC dies or chiplets are being prepared for hybrid bonding. For example, substrate 201 may be a monolithic material, a crystalline material, or a composite material, structural material or substrate 201 may be a base substrate including an interconnect layer, optional device layer, and routing through substrate 201 for connection to an outside package or board. Substrate 201 may include any suitable material or materials such as a semiconductor material such as monocrystalline silicon (Si), germanium (Ge), silicon germanium (SiGe), III-V materials (e.g., gallium arsenide (GaAs)), silicon carbide (SiC), sapphire (Al₂O₃), or any combination thereof.

Hybrid bonding layer 202 includes metal bond pads 203 interspersed in an inorganic dielectric material 204. Inorganic dielectric material 204 may be any suitable material for forming a bond between hybrid bonding layer 202 and another hybrid bonding layer. As used herein, the term inorganic material indicates materials not having carbon as a foundational component or materials not having carbon-hydrogen bonds. In some embodiments, inorganic dielectric material 204 is silicon oxide. In some embodiments, inorganic dielectric material 204 is silicon nitride, silicon oxynitride, silicon carbonitride, or silicon carbide. In some embodiments, the out facing surface of hybrid bonding layer 202 may be planarized to a smooth finish for subsequent bonding. Metal bond pads 203 may be any suitable material for forming a bond between hybrid bonding layer 202 and another hybrid bonding layer and a suitable conductor for the application at hand. In some embodiments, metal bond pads 203 are copper but other metals may be used. In some embodiments, a bulk inorganic dielectric material is formed over substrate 201 and planarized. Metal bond pads 203 are then formed using any suitable technique or techniques such as single or dual damascene techniques.

FIG. 3 illustrates an IC structure 300 similar to IC structure 200 after formation of hydrophilic structures 301 for self-aligned bonding and superhydrophobic structures 311 for containment of a liquid droplet during the self-aligned bonding. As discussed, hydrophilic structures 301 include metal bond pads 203 (e.g., copper bond pads) interspersed in inorganic dielectric material 204, which may be silicon oxide, silicon nitride, silicon oxynitride, silicon carbonitride, or silicon carbide. Such materials are hydrophilic such that a liquid (e.g., water) will spread out on hydrophilic structures 301 as the liquid minimizes its surface energy. Patterned hydrophilic structures 301 therefore define hybrid bonding regions 303, which will be bonded to corresponding hybrid bonding regions to build 3D die stacks or structures, as discussed further herein below.

Hydrophilic structures 301 and superhydrophobic structures 311 may be formed from hybrid bonding layer 202 using any suitable technique or techniques such as patterning a resist layer on or over hybrid bonding layer 202, etching the exposed portions of hybrid bonding layer 202 (e.g., via dry etch), and removing the resist layer. In some embodiments, trenches 302 are formed between superhydrophobic structures 311. In some embodiments, superhydrophobic structures 311 extend between hydrophilic structures 301 within trenches 302. In some embodiments, the pattern of hydrophilic structures 301, as defined by hybrid bonding regions 303, matches a desired layout of chiplets or IC dies on substrate 201.

As shown, superhydrophobic structures 311 may be formed within trenches 302 and adjacent sidewalls 305 using any suitable technique or techniques such as those discussed with respect to FIGS. 11-14. Superhydrophobic structures 311, which may be characterized as hydrophobic structures, hydrophobic regions, or the like may include any suitable shapes and structures that has locally hydrophobic material surfaces and gaps between the hydrophobic material surfaces shapes that create very low surface area contact with the alignment liquid relative to the planar area of the hybrid bonding regions. For example, a lateral contact surface area may be defined (for a particular region) by a sum of the areas of rods 321 in the x-y plane. Furthermore, a total lateral surface area of the particular region includes the sum of the areas of rods 321 and the gaps between rods 321, again taken in the x-y plane. In some embodiments, the contact surface area of the hydrophobic material surfaces shapes is not more than 50% of the total area. In some embodiments, the contact surface area of the hydrophobic material surfaces shapes is not more than 25% of the total area. In some embodiments, the contact surface area of the hydrophobic material surfaces shapes is not more than 10% of the total area. The same contact surface area to total areas discussed with respect to rods 321 may hold for any superhydrophobic structures discussed herein. In some embodiments, rods 321 extend in a direction orthogonal to a bonding plane of hydrophilic structures 301, as defined by hybrid bonding regions 303. For example, the bonding plane as defined by hybrid bonding regions 303 is in the x-y plane while the rods or needles of superhydrophobic structures 311 may have an axis that extends in the z-direction. However, rods 321 may extend along a variety of directions. As shown, superhydrophobic structures 311 are laterally adjacent to and extend around an outer perimeter of hybrid bonding regions 303, including an outer perimeter of metal bond pads 203 and inorganic dielectric material 204.

As shown in expanded view 310, in some embodiments, superhydrophobic structures 311 include rods 321 having a long axis extending in the x-direction and substantially orthogonal to the x-y plane of the bonding plane defined by hybrid bonding regions 303. As discussed, a needle or rod is a structure having an aspect ratio defined as a height h of the needle or rod divided by a maximum cross-sectional width w of the needle or rod (i.e., AR=h/w) that is not less than one.

In some embodiments, the superhydrophobic structures such as superhydrophobic structures 311 are in trenches 302 between hybrid bonding regions 303, but not all the way to the edge so that the superhydrophobic structures do not form the edge(s) of hybrid bonding regions 303. Furthermore, it is noted that an IC die being attached to hybrid bonding regions 303 may also include the superhydrophobic structures. The edge of hybrid bonding regions 303 may match with the edge of the IC die, and the superhydrophobic structures cannot typically extend all the way to the edge of the IC die.

A cross-sectional width or maximum cross-sectional width of a feature is defined as the maximum width across the feature (regardless of shape) such that the width extends between sides of the shape and through the centroid of the shape. For example, for a circular shape, the cross-sectional width is a diameter, for a rectangular shape, the cross-sectional width is the longest side, and so on. For example, the cross-sectional width is a characteristic in-plane dimension of rods 321. In some embodiments, rods 321 have a cross-sectional width w that is not more than 100 microns. In some embodiments, rods 321 have a cross-sectional width w that is in the range of 5 nanometers to 100 microns. In some embodiments, rods 321 have a cross-sectional width w that is not more than 10 microns. In some embodiments, rods 321 have a cross-sectional width w that is not more than 1 micron. In some embodiments, rods 321 have a cross-sectional width w that is not more than 500 nm. In some embodiments, rods 321 have a cross-sectional width w that is not more than 100 nm. In some embodiments, rods 321 have a cross-sectional width w that is not more than 50 nm. In some embodiments, rods 321 have a cross-sectional width w that is not more than 20 nm. Other widths may be used. In some embodiments, the width of multiple rods is defined as the maximum width of all the rods. In some embodiments, the width of multiple rods is defined as the average width of all the rods.

Furthermore, a height of features such as rods 321 is defined as the vertical length from a top point or surface of the feature to the base of the feature. In some embodiments, the height of multiple rods is defined as the maximum height of all the rods. In some embodiments, the height of multiple rods is defined as the average height of all the rods. As discussed, in some embodiments, rods 321 have an aspect ratio AR that is not less than one. For example, rods 321 may have a height h substantially equal to any of the discussed widths w. In some embodiments, In some embodiments, rods 321 have an aspect ratio AR that is not less than two. In some embodiments, rods 321 have an aspect ratio AR that is not less than five. In some embodiments, In some embodiments, rods 321 have an aspect ratio AR that is in the range of two to ten. For example, an aspect ratio AR of rods 321 of not less than one provides reliable superhydrophobicity for superhydrophobic structures 311. Increasing the aspect ratio AR of rods 321 to the range of two to ten does not significantly increase superhydrophobicity but can provide more robust liquid droplet pinning during assembly. However, further increasing the aspect ratio can lead to processing difficulties and failures of rods 321. In some embodiments, the aspect ratio AR of multiple rods is defined as the minimum aspect ratio of all the rods. In some embodiments, the aspect ratio AR of multiple rods is defined as the average aspect ratio of all the rods. Notably, exemplary heights h of rods 321 may be determined based on the discussed example widths and aspect ratios.

In addition to considerations of width and aspect ratio of rods 321, another important aspect is the pitch of rods 321. The term pitch is defined as the lateral distance between like features of rods 321. Such like features may be a same lateral edge (as shown) such as an edge that is furthest in the negative x-direction or other lateral direction, a centerpoint, or the like. Notably, the features used on each of rods 321 to determine pitch p must be the same feature type. In some embodiments, the pitch p of rods 321 have a pitch p that is substantially the same as the width w of rods 321. Notably, a substantially equal pitch and width of rods 321 offers an advantageous combination of surface contact at tops of rods 321 and space between rods seen by a liquid droplet. For example, if the pitch p is too small, rods 321 are too close together and there is too much surface contact with a liquid droplet. While, if pitch p is too large, a liquid droplet can flow between rods 321. A key to superhydrophobicity is the array of rods 321 having space between rods 321 such that a liquid droplet (e.g., water) is repelled from the pores or spaces between rods 321, which results in a minimal liquid/solid interfacial area.

In some embodiments, pitch p is defined as a multiple of width w. In some embodiments, rods 321 have a feature pitch p of not less than 150% of cross-sectional width w and not more than 500% of cross-sectional width w. In some embodiments, rods 321 have a feature pitch p of not less than 150% of cross-sectional width w and not more than 400% of cross-sectional width w. In some embodiments, rods 321 have a feature pitch p of not less than 200% of cross-sectional width w and not more than 300% of cross-sectional width w. In some embodiments, rods 321 have a feature pitch p of not more than 250% of cross-sectional width w. Other pitches may be used. In some embodiments, the pitch across a number of rod pairs is defined as the minimum or maximum pitch. In some embodiments, the pitch across a number of rod pairs is defined as the average of the pitches.

As shown in top-down view 320, taken at A-A′ of expanded view 310, in some embodiments, rods 321 are in a grid array 322 such that rows of rods 321 are aligned in the x-direction and columns of rods 321 are aligned in the y-direction. Top-down view 320 also illustrates rods 321 may have the same cross-sectional widths w and may have a circular cross-sectional shape, in some embodiments. In other embodiments, rods 321 may have differing cross-sectional widths w. Furthermore, rods 321 may have any cross-sectional shapes such as square or rectangular (with rounded edges in some examples), oval, or others. All of rods 321 may have the same shapes or mixes of shapes may be used. Furthermore, as shown in top-down view 330, also taken at A-A′ of expanded view 310, in some embodiments, rods 321 are in a substantially random pattern 332 such that rows/columns of rods 321 are not established by pattern 332.

As shown in FIG. 3, in some embodiments, rods 321 have flat top surface 323 and a cross-sectional shape that is substantially constant through the depth (i.e., in the z-dimension) of rods 321. In other embodiments, rods 321 may have rounded top.

FIG. 4 illustrates an IC structure 410 in an expanded view similar to that of expanded view 310 of FIG. 3, with superhydrophobic structures 311 having rods 421 with rounded tops 401. Rods 421 may have any features or characteristics discussed with respect to rods 321 with the exception that rods 421 have rounded tops 401 having a top (e.g., a top position, apex, or the like) having a curved surface and defining height h of rods 421. Rounded tops 401 may have any suitable characteristics. In some embodiments, rounded tops 401 have a radius of curvature approximately equal to a half of cross-sectional width w. In some embodiments, the radius of curvature is in the range of 80% to 120% of half of cross-sectional width w.

FIG. 5 illustrates an IC structure 510 in an expanded view similar to that of expanded view 310 of FIG. 3, with superhydrophobic structures 311 having needles 521 with pointed tops 501. Needles 521 may have any features or characteristics discussed with respect to rods 321 with the exception that needles 521 have pointed tops 501 having a top (e.g., a top position, apex, or the like) coming to a minimal dimension of about 1 nm and defining height h of needles 521. Pointed tops 501 may have any suitable characteristics. In some embodiments, pointed tops 501 have a surface or surfaces 502 extending therefrom that establish an angle a of pointed tops 501 in the range of about 30 to 60 degrees. In some embodiments, the angle a is in the range of 40 to 50 degrees.

FIG. 6 illustrates an IC structure 610 in an expanded view similar to that of expanded view 310 of FIG. 3, with superhydrophobic structures 311 having needles 621 with pointed tops 601 and slanted sidewalls 602 such that needles 621 have a pyramid or cone shape. Tapered structures such as those illustrated with respect to needles or needles 621 may increase the contact angle (CA) further by minimizing potential water to solid contact area. Needles 621 may have any features or characteristics discussed with respect to rods 321 with the exception that needles 621 have pointed tops 601 having a top (e.g., a top position, apex, or the like) coming to a minimal dimension of about 1 nm and defining height h of needles 621, as well as slanted sidewalls 602 that extend from pointed top 601 to a base 603 of needles 621.

In some embodiments, slanted sidewalls 602 extended from pointed top 601 to establish an angle a in the range of about 30 to 60 degrees. In some embodiments, the angle a is in the range of 40 to 50 degrees. In some embodiments, a first cross-sectional width w1 of needles 621 is established at a location or position p1 between 10 to 100 nm from a top location or position p0 of needles 621, and a second cross-sectional width w2 of needles 621 is established at a location p2 about 500 nm to 1 micron from top p0 of needles 621. First cross-sectional width w1 may have any characteristics or dimensions discussed with cross-sectional width w above (as may height h and pitch p). Cross-sectional width w2 may be any suitable multiple of width w2. In some embodiments, cross-sectional width w2 is not less than twice cross-sectional width w1. In some embodiments, cross-sectional width w2 is not less than three times cross-sectional width w1.

As discussed with respect to operation 103, optional second order hydrophobic structures may be formed on the rods or needles. Such second order hydrophobic structures may be fabricated using any suitable technique or techniques. In some embodiments, fabrication of the primary needles or rods is performed, for example, lithography and etch techniques, or catalyst deposition followed by growth based on nucleation from the catalyst. For example, lithography and etch techniques may form ordered grid array 322 of any of rods 321, 421, 521, 621 while catalyst/nucleation techniques may be used to form random pattern 332 of any of rods 321, 421, 521, 621 or (see FIG. 3). After fabrication of the primary needles or rods, second order hydrophobic structures may be fabricated on or from the primary rods. In some embodiments, the second order hydrophobic structures are needles or rods grown from the primary needles or rods using, for example, catalyst and nucleation growth techniques. In addition, third or even fourth order hydrophobic structures may be grown from the second or third hydrophobic structures using iterative processing. In some embodiments, the second order hydrophobic structures are formed by a surface treatment of the primary needles or rods to form a roughened surface.

FIG. 7 illustrates an IC structure 710, in an expanded view, similar to IC structure 300 after formation of secondary hydrophobic structures 701 on rods 321. Although illustrated with respect to secondary hydrophobic structures 701 being formed on rods 321, secondary hydrophobic structures 701 may be formed on any of rods/needles 421, 521, 621 or any other structure discussed herein. As discussed, secondary hydrophobic structures 701 may be formed using any suitable technique or techniques. In some embodiments, a catalyst material is deposited on rods 321 (and optionally removed using lithography and etch techniques from other exposed surfaces) and secondary hydrophobic structures 701 are grown from the catalyst material. In some embodiments, surface roughening techniques are used to form secondary hydrophobic structures 701. Secondary hydrophobic structures 701 may be the same material as rods 321 or the materials may be different (as shown).

Secondary hydrophobic structures 701 may have any suitable size or shape. In some embodiments, secondary hydrophobic structures 701 are also needle or rod shaped but at a smaller dimension than that of rods 321. In some embodiments, secondary hydrophobic structures 701 include a number of rods extending from each of rods 321, such that the rods of secondary hydrophobic structures 701 have a cross-sectional width w3 of not more than 50% of the cross-sectional width w of rods 321. In some embodiments, cross-sectional width w3 is not more than 40% of the cross-sectional width w of rods 321. In some embodiments, cross-sectional width w3 of not more than 25% of the cross-sectional width w of rods 321.

In addition, in some embodiments, tertiary hydrophobic structures (i.e., third order hydrophobic structures, not shown) of any suitable size or shape may be formed off of secondary hydrophobic structures 701 in an analogous manner. In some embodiments, the tertiary hydrophobic structures are also needle or rod shaped but at a smaller dimension than that of secondary hydrophobic structures 701. For example, the tertiary hydrophobic structures may have a cross-sectional width not more than 50%, not more than 40%, or not more than 25% cross-sectional width w3 of secondary hydrophobic structures 701.

As discussed with respect to operation 104, an optional hydrophobic material layer may be formed on the rods or needles. The hydrophobic material layer may be formed using any suitable technique or techniques. In some embodiments, a conformal hydrophobic material layer is formed on exposed surfaces using, for example, spin coating or conformal vapor deposition. The conformal hydrophobic material layer may then be selectively removed using lithography and etch techniques to leave the hydrophobic material layer only on the rods or needles.

FIG. 8 illustrates an IC structure 810, in an expanded view, similar to IC structure 300 after formation of hydrophobic material layer 801 on rods 321. Although illustrated with respect to hydrophobic material layer 801 being formed on rods 321, hydrophobic material layer 801 may be formed on any of rods/needles 421, 521, 621 or any other structure discussed herein such as a structure having rods/needles and secondary hydrophobic structures. Hydrophobic material layer 801, which may be characterized as a hydrophobic surface, hydrophobic coating, or the like may include any suitable hydrophobic material (e.g., material that causes a liquid water droplet to have a contact angle of greater than) 90°. In some embodiments, hydrophobic material layer 801 is a chemical coating or hydrophobic material that creates a hydrophobic boundary with a large contact angle (e.g., >) 90° even absent the structural aspect of superhydrophobic structures 311.

In some embodiments, hydrophobic material layer is or includes a self-assembled monolayer (SAM) material such as an alkyl or fluoroalkyl silane (e.g., ODS, FDTS), a thiol (e.g., hexadecane thiol), a phosphonic acid (e.g., octadecyl or perfluorooctane phosphonic acid), or an alkanoic acid (e.g., heptadecanoic acid). However, non-SAM based materials or films may be used. In some embodiments, hydrophobic material layer is or includes a thin polymer film such as a siloxane (e.g., PDMS and derivatives, HMDSO), a silazane (HMDS), a polyolefin (e.g., PP), or a fluorinated polymer (e.g., PTFE, PFPE, PFDA, C4F8 plasma polymerized films, etc.). Other hydrophobic materials may be used. In accordance with some embodiments of the present disclosure, hydrophobic material layer 801 may be or may include a layer of material having an atomic composition of at least 10% carbon, a layer of material having an atomic composition of at least 10% fluorine, a layer of material having an atomic composition of at least 10% phosphorus, a layer of material having an atomic composition of at least 10% sulfur, and/or or a layer of material having an atomic composition of at least 10% silicon.

As discussed, in some embodiments, superhydrophobic structures 311 may be fabricated from inorganic dielectric material 204 (refer to FIGS. 2 and 3). In other embodiments, superhydrophobic structures 311 may be fabricated from substrate 201. For example, superhydrophobic structures may be formed from a hybrid bonding material (e.g., FIGS. 2-8) or from a substrate material (e.g., FIGS. 9 and 10), with FIGS. 11-14 illustrating exemplary superhydrophobic structure fabrication in either context.

FIG. 9 is an illustration of a cross-sectional side view of an IC structure 900 being prepared for self-alignment bonding. IC structure 900 includes hydrophilic structures 301 embedded in and adjacent portions 901 of substrate 201. IC structure 900 may be fabricated using any suitable technique or techniques such as using lithography and etch techniques to form openings corresponding to hydrophilic structures 301. The openings may be filled with inorganic dielectric material 204. Following planarization, metal bond pads 203 may then be formed using any suitable technique or techniques such as single or dual damascene techniques.

FIG. 10 illustrates an IC structure 1000 similar to IC structure 900 after formation of superhydrophobic structures 1011 for containment of a liquid droplet during self-aligned bonding. As discussed, hydrophilic structures 301 include metal bond pads 203 (e.g., copper bond pads) interspersed in inorganic dielectric material 204, which may be silicon oxide, silicon nitride, silicon oxynitride, silicon carbonitride, or silicon carbide. Such materials are hydrophilic such that a liquid (e.g., water) will spread out on hydrophilic structures 301 as the liquid minimizes its surface energy, and hydrophilic structures 301 define hybrid bonding regions 303.

Superhydrophobic structures 1011 may be formed from portion 901 of substrate 201 using any suitable technique or techniques such as patterning a resist layer, etching the exposed portions of substrate 201, and removing the resist layer. In some embodiments, trenches 302 are formed between superhydrophobic structures 1011. Superhydrophobic structures 1011 may have any characteristics discussed with respect to superhydrophobic structures 311 with the exception that superhydrophobic structures 1011 are the same material as substrate 201. For example, superhydrophobic structures 1011 may be monocrystalline silicon (Si), germanium (Ge), silicon germanium (SiGe), III-V materials (e.g., gallium arsenide (GaAs)), silicon carbide (SiC), sapphire (Al₂O₃), or any combination thereof.

Discussion now turns to fabrication of needles or rods using lithography and etch techniques, surface roughening the needles or rods to provide secondary hydrophobic structures, and coating the resultant needles or rods with a hydrophobic material layer. Such techniques are exemplary embodiments of those techniques discussed with respect to operations 102, 103, and 104.

FIG. 11 is an illustration of a cross-sectional side view of an IC structure 1100 being prepared for self-alignment bonding. As shown, IC structure 1100 includes an underlying material or substrate 1101 and a patterned layer 1102 formed on substrate 1101. Substrate 1101 may be substrate 201 or inorganic dielectric material 204 as discussed herein. For example, the processing discussed with respect to FIGS. 11-14 may be performed on a substrate material, or an inorganic material also used as a portion of a hybrid bonding structure (e.g. SiO₂), or other material. Patterned layer 1102 may include any material or materials such as a photoresist, a hardmask material, or the like. In some embodiments, patterned layer 1102 is formed using lithography techniques.

FIG. 12 is an illustration of a cross-sectional side view of an IC structure 1200 similar to IC structure 1100 after fabrication of rods 1202 and openings 1201. Rods 1202 may be any rods discussed herein such as rods 321, 421, 521, 621. Rods 1202 may be fabricated from substrate 1101 using any suitable technique or techniques such as anisotropic etch techniques such as anisotropic dry etch or anisotropic wet etch. Rods 1202 may have any characteristics discussed elsewhere herein. After formation of rods 1202 and openings 1201, patterned layer 1102 may be removed using any suitable technique or techniques such as ashing techniques.

FIG. 13 is an illustration of a cross-sectional side view of an IC structure 1300 similar to IC structure 1200 after roughening the surface of rods 1202 to form secondary hydrophobic structures 1301. Secondary hydrophobic structures 1301 may be formed using any suitable technique or techniques such as a short isotropic etch process. The isotropic etch may also oxidize the surface of rods 1202, depending on the material deployed. Secondary hydrophobic structures 1301 may have any suitable characteristics. In some embodiments, secondary hydrophobic structures 1301 include one or more indents or dimples 1302 having a surface that is inset by a distance d from an outer surface of rods 1202. Distance d may be any suitable dimension such as an inset distance d of not less than 5 nm. In some embodiments, the inset distance d is not less than 10 nm. In some embodiments, the inset distance d is not less than 20 nm. In some embodiments, the inset distance d is not less than 5% of cross-sectional width w of rods 1202. In some embodiments, the inset distance d is not less than 10% of cross-sectional width w of rods 1202. In some embodiments, the inset distance d is not less than 20% of cross-sectional width w of rods 1202.

FIG. 14 illustrates an IC structure 1400 similar to IC structure 1300 after formation of hydrophobic material layer 801 on rods 1202. Hydrophobic material layer 801 may include any suitable hydrophobic material discussed above. Hydrophobic material layer 801 may be formed using any suitable technique or techniques such as conformal deposition followed by patterning. In some embodiments, hydrophobic material layer 801 selective self assembles to rods 1202

Returning to FIG. 1, process 100 continues at operation 105, where IC dies or chiplets are self-assembled onto a base wafer using a liquid droplet between hybrid bonding regions and within the superhydrophobic containment features prepared as discussed herein. In some embodiments, the water droplet is applied to a hydrophilic hybrid bonding region over a base substrate. In some embodiments, the water droplet is applied to a hydrophilic hybrid bonding region of the IC dies or chiplets. In either event, the IC die hydrophilic hybrid bonding region is placed on or over the hydrophilic bonding region of the base substrate (using gross alignment) and the interplay of the droplet, the hydrophilic bonding regions, and the superhydrophobic containment features cause the IC die to self-align with high accuracy.

FIG. 15 is an illustration of a cross-sectional side view of an IC structure 1500 during self-alignment bonding. As shown, IC structure 1500 includes hydrophilic structures 301 on or over a base substrate 1501 and superhydrophobic structures 311 adjacent hydrophilic structures 301 and also on or over base substrate 1501. Although illustrated with respect to hydrophilic structures 301 and superhydrophobic structures 311, any hydrophilic structures and superhydrophobic structures discussed herein may be deployed in the following structures. Superhydrophobic structures 311 and adjacent hydrophilic structures 301 may be formed over base substrate 1501 using any suitable technique or techniques discussed above.

As shown, base substrate 1501 includes an active layer 1502. Active layer 1502 (or an active surface) includes a device layer and/or an interconnect layer. For example, a device layer may include transistors, capacitors, or other IC devices. An interconnect layer may be over the device layer and may include metallization levels that interconnect the devices of the device layer and provide routing to outside devices. In some embodiments, base substrate 1501 includes active devices in active layer 1502 and routing from active layer 1502 to a backside surface 1511 of base substrate 1501. In some embodiments, base substrate 1501 includes routing from active layer 1502 to backside surface 1511, and is absent active devices. Base substrate 1501 may include any suitable material or materials such as a semiconductor material such as monocrystalline silicon (Si), germanium (Ge), silicon germanium (SiGe), III-V materials (e.g., gallium arsenide (GaAs)), silicon carbide (SiC), sapphire (Al₂O₃), or any combination thereof. As discussed, a base substrate, base wafer, or base die indicates a substrate having active or passive electrical features. In some embodiments, a multi-level stack of IC dies is formed over base substrate 1501 using die-to-wafer bonding and 3D die complexes are segmented from base substrate 1501 such that each 3D die complex includes a portion of base substrate 1501 and the pertinent attached chiplets over the segmented portion of base substrate 1501.

Furthermore, each of IC dies 1521 includes a substrate 1523, an active layer 1522, and through vias 1524 extending between active layer 1522 and a backside surface 1507 of each of IC dies 1521. Active layer 1522 (or an active surface), similar to active layer 1502, includes a device layer and/or an interconnect layer. For example, the device layer may include transistors, capacitors, or other IC devices. The interconnect layer may be over the device layer and may include metallization levels that interconnect the devices of the device layer and provide routing to outside devices. Substrate 1523 may include any suitable material or materials such as a semiconductor material such as monocrystalline silicon (Si), germanium (Ge), silicon germanium (SiGe), III-V materials (e.g., gallium arsenide (GaAs)), silicon carbide (SiC), sapphire (Al₂O₃), or any combination thereof. Backside surface 1507 is opposite active layer 1522 and may be characterized as a non-active surface.

On or over each of IC dies 1521, hydrophilic structures 1517 (analogous to hydrophilic structures 301) and superhydrophobic structures 1515 (analogous to superhydrophobic structures 311) are formed as discussed herein above to define hybrid bonding regions 1527. For example, hydrophilic structures 1517 include metal bond pads 1514 and inorganic dielectric material 1513, which may have any characteristics discussed with respect to metal bond pads 203 and inorganic dielectric material 204. Similarly, superhydrophobic structures 1515 may have any characteristics discussed with respect to superhydrophobic structures 311 and, although illustrated with respect to superhydrophobic structures 1515 being similar to superhydrophobic structures 311, any superhydrophobic structures discussed herein may be deployed. Hydrophilic structures 1517 and superhydrophobic structures 1515 may be formed over a wafer including one or more of IC dies 1521 using the techniques discussed above, and IC dies 1521 may be segmented (e.g., diced) from the wafer for pick and place onto hybrid bonding regions 303, for example. The combination of hydrophilic structures/superhydrophobic structures over base substrate 1501 and the combination of hydrophilic structures/superhydrophobic structures on IC dies 1521 may be the same (as shown) or they may be different.

As shown, liquid droplets 1506 are placed on hybrid bonding regions 303 of hydrophilic structures 301 (or on hybrid bonding regions 1527 of hydrophilic structures 1517). Liquid droplets 1506 may be any suitable liquid such as water of any suitable volume. Hybrid bonding regions 303 and hybrid bonding regions 1527 are brought together using, for example, pick and place of IC dies 1521. As shown, liquid droplets 1506 spread out on hybrid bonding regions 303 (or hybrid bonding regions 1527) and are contained by superhydrophobic structures 311 (or superhydrophobic structures 1515). IC dies 1521 are grossly and advantageously quickly aligned to hybrid bonding regions 303 and liquid droplets 1506 by pick and place 1582, confined by the self-alignment assisting features discussed herein, quickly fine align each of IC dies 1521 to the corresponding hybrid bonding region 303.

IC dies 1521 may be fabricated and attached such that they are in a face-down configuration 1531 or a face-up configuration 1532. In face-down configuration 1531, active layer 1502 and active layer 1522 are adjacent one another and are directly connected by a hybrid bond therebetween, as discussed further below. Advantageously, through vias 1524 (which may be characterized as through substrate vias or through silicon vias, TSVs), have backside connections on or over backside surface 1507 such that routing from the hybrid bond and active layer 1522 is provided to additional IC dies in the stack (e.g., extending in the z-dimension). In face-up configuration 1532, active layer 1522 is opposite substrate 1523 with respect to active layer 1522. In such contexts, through vias 1524 again have backside connections on or over backside surface 1507 such that routing from the hybrid bond may be provided to active layer 1522, and then to additional IC dies in the stack (e.g., extending in the z-dimension).

Returning to FIG. 1, process 100 continues at operation 106, where the IC dies or chiplets are bonded to the base substrate or wafer by evaporating the liquid droplets and anneal processing. For example, the liquid droplet applied at operation 105 evaporates relatively quickly after alignment and the inorganic materials hold the IC dies or chiplets in place due to, for example, Van der Waals forces. A subsequent anneal operation may be performed to bond the IC dies or chiplets to the bonding regions of the structural wafer by melding metal bond pads and the inorganic materials therebetween.

FIG. 16 is an illustration of a cross-sectional side view of an IC structure 1600 similar to IC structure 1500 after liquid droplets 1506 evaporate and after bonding to form composite metal structures 1601 and a composite dielectric portion 1602 between each of IC dies 1521 and base substrate 1501. Furthermore, superhydrophobic structures 311, 1515 may bond to form composite superhydrophobic structures 1603. In other contexts, no bonding between superhydrophobic structures 311, 1515 occurs. As shown, IC structure 1600 includes base substrate 1501 coupled to active layers 1522 or backside surfaces 1507 of each IC die 1521, depending on whether each IC dies was in face-down configuration 1531 or face-up configuration 1532 during bonding.

As shown, the discussed hybrid bonding forms composite metal structures 1601 and a composite dielectric portion 1602 across a bonding plane 1643. Thereby, a hybrid bond 1621 between IC dies 1521 and base substrate 1501 is formed. Each hybrid bond 1621 includes composite metal structures 1601 and composite dielectric portion 1602. Composite dielectric portion 1602 may be characterized as an inorganic material, an inorganic bond layer, an inorganic bonding material, or the like. As shown, each hybrid bond 1621 is surrounded by composite superhydrophobic structures 1603 or by the pertinent superhydrophobic structures deployed in forming hybrid bond 1621.

As shown in insert 1612, in some embodiments, adjacent metal pads are annealed to form a composite metal structure 1613 (one of composite metal structures 1601) such that metal structure 1613 has a substantially aligned sidewalls 1623. However, in other embodiments, adjacent metal bond pads 203, 1514 have a misalignment 1614 during anneal and form a composite metal structure 1633 such that metal structure 1633 has a substantially misaligned sidewalls and therefore metal structure 1633 includes a jut 1624 and an overhang 1625. For example, the sidewall of metal structure 1633 may have substantially vertical sidewall portions and a substantially horizontal sidewall portion (e.g., at jut 1624 and overhang 1625).

Similarly, as shown in insert 1622, in some embodiments, adjacent superhydrophobic structures 311, 1515 form a composite superhydrophobic structure 1663 (e.g., any of composite superhydrophobic structures 1603) that has substantially aligned sidewalls 1673. However, in other embodiments, adjacent superhydrophobic structures 311, 1515 have a misalignment 1664 during anneal and form a composite hydrophobic structure 1683 (e.g., any of superhydrophobic structures 1603) that has a substantially misaligned sidewall 1674 and therefore superhydrophobic structure 1683 includes a jut or overhang 1675. For example, the sidewall of superhydrophobic structure 1683 may have substantially vertical sidewall portions and a substantially horizontal sidewall portion. In some embodiments, composite superhydrophobic structure 1603 extends from a surface of active layer 1502 to active layer 1522 or backside surface 1507 of IC dies 1521.

As discussed, each hybrid bond 1621 is surrounded (entirely or mostly, i.e., >90%) by superhydrophobic structures 1603. In the context of FIG. 16, superhydrophobic structures 1603 are formed of superhydrophobic structures 311, 1515, though the materials of superhydrophobic structures 311, 1515 may not combine or meld. As shown in FIG. 16, superhydrophobic structure 1603 extends around a perimeter P1 of hybrid bond 1621. As used herein, the term perimeter is used in its ordinary meaning to indicate an outer boundary of superhydrophobic structure 1603 in the x-y plane. For perimeters that are not taken in the same plane, such perimeters are projected into the same plane for determination of their dimensions. Furthermore, an outer perimeter P2 of superhydrophobic structure 1603 is fully within an outer perimeter P3 of IC die 1521. It is noted that a single continuous superhydrophobic structure 1603 may surround hybrid bond 1621 or multiple discontinuous superhydrophobic structures 1603 may surround hybrid bond 1621.

Returning to FIG. 1, process 100 continues at operation 107, where a gap fill dielectric is formed between the IC dies and planarized to provide a planar top surface and the structure is attached to a structural substrate such as a structural wafer. In some embodiments, the gap fill dielectric is an inorganic dielectric material such as silicon nitride, silicon oxynitride, silicon carbonitride, or silicon carbide. The gap fill dielectric may be formed using any suitable technique or techniques such as deposition techniques followed by planarization. In some embodiments, the IC structure is bonded to the structural substrate in a wafer-to-wafer bond using an adhesive, an adhesive tape, a dielectric bond, or the like. The structural substrate may be a structural wafer or panel or the like that is absent any active or passive electrical features. For example, the structural substrate may be a monolithic material, a crystalline material, or a composite material. In some embodiments, the structural substrate is monocrystalline silicon such as a silicon wafer. In some embodiments, the structural substrate is or includes germanium, silicon germanium, silicon carbide, or sapphire.

FIG. 17 is an illustration of a cross-sectional side view of IC structure 1700 similar to IC structure 1600 after forming inorganic dielectric 1701 and a substantially planar surface 1702. As shown, inorganic dielectric 1701 may be deposited as a fill material using any suitable technique or techniques such as vapor deposition techniques. The fill material is then planarized using chemical mechanical polishing techniques, to form planar surface 1702. Inorganic dielectric 1701 may be any material suitable dielectric material such as silicon oxide, silicon nitride, silicon oxynitride, silicon carbonitride, silicon carbide, or combinations thereof (e.g., a layer of one of those materials covered by a second layer of another one of those materials). Although inorganic dielectric materials may be advantageous, organic dielectrics may be deployed. As discussed below, planar surface 1702 provides a surface for a subsequent level of IC dies or chiplets in a multi-level 3D die stack.

FIG. 18 is an illustration of a cross-sectional side view of IC structure 1800 similar to IC structure 1700 after bonding IC structure 1700 to a structural substrate 1801. Structural substrate 1801 may be bonded to IC structure 1100 using an adhesive, an adhesive tape, or the like (not shown). Structural substrate 1801 may be a structural wafer or panel and is absent any active or passive electrical features. In some embodiments, structural substrate 1801 is or includes monocrystalline, germanium, silicon germanium, silicon carbide, or sapphire. In some embodiments, structural substrate 1801 provides structural support during further processing (e.g., dicing, packaging, assembly, etc.). For example, base substrate 1501 may be thinned while IC structure 1700 is mounted to structural substrate 1801. After such processing and during deployment in an electronic device, structural substrate 1801 may provide a heat conduction path while continuing to provide structural support.

Returning to FIG. 1, process 100 continues at operation 108, where the integrated circuit structure is segmented (or diced) from the wafer-to-wafer bonded stack. For example, IC structure 1800, or any other IC structure discussed herein may be segmented from a wafer using known dicing techniques. Process 100 continues at operation 109, where the resultant device (e.g., IC structure) may be packaged, assembled, and implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

FIG. 19 illustrates an example microelectronic device assembly 1900 including a 3D die stack having a hybrid bond with a superhydrophobic surface around an outer perimeter of the hybrid bond, in accordance with some embodiments. For example, FIG. 19 is an illustration of a cross-sectional side view of an assembly structure similar to IC structure 1800 after packaging and deployment of heat removal solutions. As shown, IC structure 1800 may be incorporated into microelectronic device assembly 1900. Although illustrated with respect to the superhydrophobic structures of FIG. 3, IC structure 1800 and, in turn, microelectronic device assembly 1900, may include any superhydrophobic structures discussed herein. Furthermore, microelectronic device assembly 1900 may deploy any IC structure discussed herein. Microelectronic device assembly 1900 may include any number of IC structures 1800 mounted to a substrate 1911 via interconnects 1909, which are optionally embedded in a mold or underfill material 1912. Substrate 1911 may be a package substrate, interposer, or board (such as a motherboard). Any number of IC structures 1800 having the same or different superhydrophobic structures may be attached to substrate 1911.

Microelectronic device assembly 1900 further includes a power supply 1956 coupled to one or more of substrate 1911 (i.e., a board, package substrate, or interposer), IC dies 1521 and/or other components of microelectronic device assembly 1900. Power supply 1956 may include a battery, voltage converter, power supply circuitry, or the like. Microelectronic device assembly 1900 further includes a thermal interface material (TIM) 1901 disposed on a top surface of structural substrate 1801. TIM 1901 may include any suitable thermal interface material and may be characterized as TIM 1. Integrated heat spreader 1902 having a surface on TIM 1901 extends over IC structure 1200 and is mounted to substrate 1911. Microelectronic device assembly 1900 further includes a TIM 1903 disposed on a top surface of integrated heat spreader 1902. TIM 1903 may include any suitable thermal interface material and may be characterized as TIM 2. TIM 1901 and TIM 1903 may be the same materials, or they may be different. A heat sink 1904 (e.g., an exemplary heat dissipation device or thermal solution) is on TIM 1903 and dissipates heat. Microelectronic device assembly 1900 may be used in desktop and server form factors. In other contexts, a heat solution such as a heat pipe or heat spreader may be mounted directly on TIM 1901. Such assemblies may be used in smaller form factor devices. Other heat dissipation devices may be used.

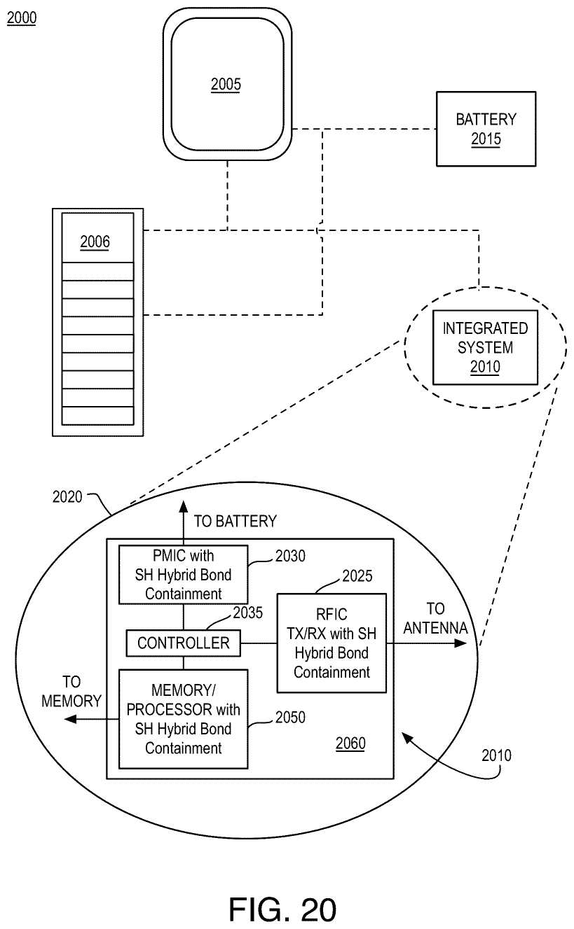

FIG. 20 illustrates an example microelectronic device system 2000 including a 3D die stack having a hybrid bond with a superhydrophobic (SH) surface around an outer perimeter of the hybrid bond, in accordance with some embodiments. The system may be a mobile computing platform 2005 and/or a data server machine 2006, for example. Either may employ a component assembly including an IC structure as described herein. Server machine 2006 may be any commercial server, for example, including any number of high-performance computing platforms disposed within a rack and networked together for electronic data processing, which in the exemplary embodiment includes an integrated circuit (IC) die assembly including a 3D die stack having a hybrid bond with a superhydrophobic material around an outer perimeter of the hybrid bond as described elsewhere herein. Mobile computing platform 2005 may be any portable device configured for each of electronic data display, electronic data processing, wireless electronic data transmission, or the like. For example, mobile computing platform 2005 may be any of a tablet, a smart phone, a laptop computer, etc., and may include a display screen (e.g., a capacitive, inductive, resistive, or optical touchscreen), a chip-level or package-level integrated system 2010, and a battery 2015. Although illustrated with respect to mobile computing platform 2005, in other examples, chip-level or package-level integrated system 2010 and a battery 2015 may be implemented in a desktop computing platform, an automotive computing platform, an internet of things platform, or the like. As discussed below, in some examples, the disclosed systems may include a sub-system 2060 such as a system on a chip (SOC) or an integrated system of multiple ICs, which is illustrated with respect to mobile computing platform 2005.

Whether disposed within integrated system 2010 illustrated in expanded view 2020 or as a stand-alone packaged device within data server machine 2006, sub-system 2060 may include memory circuitry and/or processor circuitry 2050 (e.g., RAM, a microprocessor, a multi-core microprocessor, graphics processor, etc.), a power management integrated circuit (PMIC) 2030, a controller 2035, and a radio frequency integrated circuit (RFIC) 2025 (e.g., including a wideband RF transmitter and/or receiver (TX/RX)). As shown, IC dice, such as memory circuitry and/or processor circuitry 2050 may be packaged, assembled, and implemented, such that the package includes a 3D die stack having a hybrid bond with a superhydrophobic material around an outer perimeter of the hybrid bond as described herein. In some embodiments, RFIC 2025 includes a digital baseband and an analog front end module further comprising a power amplifier on a transmit path and a low noise amplifier on a receive path). Functionally, PMIC 2030 may perform battery power regulation, DC-to-DC conversion, etc., and so has an input coupled to battery 2015, and an output providing a current supply to other functional modules. As further illustrated in FIG. 20, in the exemplary embodiment, RFIC 2025 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 2050 may provide memory functionality, high level control, data processing and the like for sub-system 2060. In alternative implementations, each of the SOC modules may be integrated onto separate ICs coupled to a package substrate, interposer, or board.

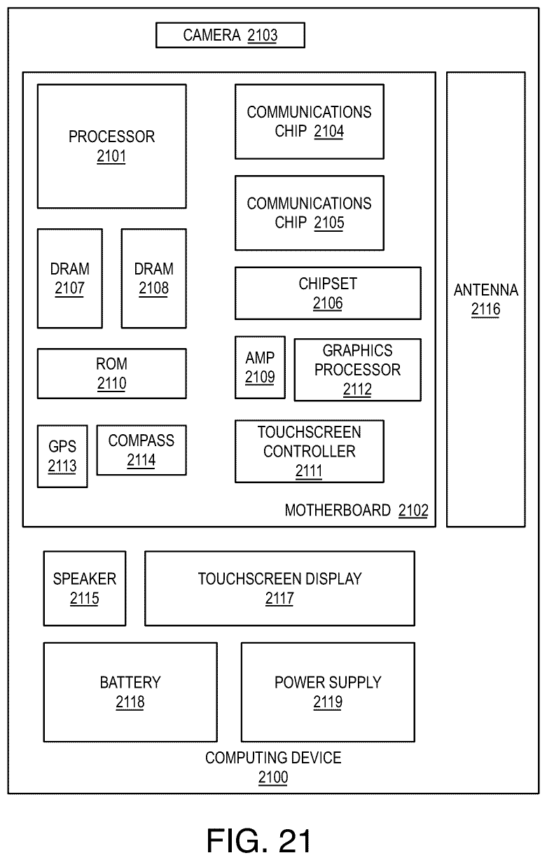

FIG. 21 is a functional block diagram of an electronic computing device 2100, in accordance with some embodiments. For example, device 2100 may, via any suitable component therein, employ a 3D die stack having a hybrid bond with a superhydrophobic material around an outer perimeter of the hybrid bond in accordance with any embodiments described elsewhere herein. Device 2100 further includes a motherboard or package substrate 2102 hosting a number of components, such as, but not limited to, a processor 2101 (e.g., an applications processor). Processor 2101 may be physically and/or electrically coupled to package substrate 2102. In some examples, processor 2101 is within a packaged IC assembly that includes a 3D die stack having a hybrid bond with a superhydrophobic material around an outer perimeter of the hybrid bond as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 2104, 2105 may also be physically and/or electrically coupled to the package substrate 2102. In further implementations, communication chips 2104, 2105 may be part of processor 2101. Depending on its applications, computing device 2100 may include other components that may or may not be physically and electrically coupled to package substrate 2102. These other components include, but are not limited to, volatile memory (e.g., DRAM 2107, 2108), non-volatile memory (e.g., ROM 2110), flash memory (e.g., NAND or NOR), magnetic memory (MRAM), a graphics processor 2112, a digital signal processor, a crypto processor, a chipset 2106, an antenna 2116, touchscreen display 2117, touchscreen controller 2111, battery 2118, a power supply 2119, audio codec, video codec, power amplifier 2109, global positioning system (GPS) device 2113, compass 2114, accelerometer, gyroscope, speaker 2115, camera 2103, and mass storage device (such as hard disk drive, solid-state drive (SSD), compact disk (CD), digital versatile disk (DVD), and so forth, or the like.

Communication chips 2104, 2105 may enable wireless communications for the transfer of data to and from the computing device 2100. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 2104, 2105 may implement any of a number of wireless standards or protocols, including, but not limited to, those described elsewhere herein. As discussed, computing device 2100 may include a plurality of communication chips 2104, 2105. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a substrate comprising an interconnect layer, an integrated circuit (IC) die coupled to the interconnect layer of the substrate by a hybrid bond between the IC die and the interconnect layer, and one or more structures laterally adjacent to and extending around an outer perimeter of the hybrid bond, wherein the one or more structures comprise a lateral contact surface area that is not more than 50% of a total lateral surface area of the one or more structures.

In one or more second embodiments, further to the first embodiments, the one or more structures comprise a plurality of rods or needles each having an aspect ratio of not less than one.

In one or more third embodiments, further to the first or second embodiments, the plurality of rods or needles each have a cross-sectional width of not more than 100 microns.

In one or more fourth embodiments, further to the first through third embodiments, the plurality of rods or needles have a feature pitch of not less than 150% of the cross-sectional width and not more than 300% of the cross-sectional width.

In one or more fifth embodiments, further to the first through fourth embodiments, the apparatus further comprises a plurality of second rods or needles extending from each of the plurality of rods or needles, wherein the second rods or needles have a second cross-sectional width of not more than 50% of a cross-sectional width of the plurality of rods or needles.

In one or more sixth embodiments, further to the first through fifth embodiments, the one or more structures comprise material surfaces defining the contact surface area and gaps between the material surfaces defining a remainder of the total surface area.

In one or more seventh embodiments, further to the first through sixth embodiments, the one or more structures comprise an inorganic dielectric material of the hybrid bond, the apparatus further comprising a material layer on the inorganic dielectric material, the material layer having an atomic composition of at least ten percent carbon or at least ten percent fluorine.

In one or more eighth embodiments, further to the first through seventh embodiments, the substrate, the IC die, and the one or more structures are part of an IC structure further comprising a structural substrate, and the apparatus or a system comprises a power supply coupled to the IC structure.

In one or more ninth embodiments, an apparatus comprises a substrate comprising an interconnect layer, an integrated circuit (IC) die coupled to the interconnect layer of the substrate by a hybrid bond that spans a bonding plane between the substrate and the IC die, the bonding plane substantially parallel to a top surface of the substrate, and the hybrid bond comprising composite metal interconnect structures interspersed in an inorganic dielectric material, and one or more structures laterally adjacent to and extending around an outer perimeter of the inorganic dielectric material, wherein the one or more structures each comprises a plurality of rods or needles having a long axis substantially orthogonal to the bonding plane, and wherein the plurality of rods or needles each have a cross-sectional width of not more than 100 microns.

In one or more tenth embodiments, further to the ninth embodiments, the plurality of rods or needles each have a cross-sectional width of not more than 100 nanometers, and wherein the plurality of rods or needles each have an aspect ratio of not less than one.

In one or more eleventh embodiments, further to the ninth or tenth embodiments, the plurality of rods or needles have a feature pitch of not less than 150% of the cross-sectional width and not more than 300% of the cross-sectional width.

In one or more twelfth embodiments, further to the ninth through eleventh embodiments, the cross-sectional width of each of the plurality rods or needles is at a location between 10 to 100 nm from a top of each of the plurality rods or needles, and wherein a second cross-sectional width of each of the plurality rods or needles at a location 500 nm from a top of each of the plurality rods is not less than twice the cross-sectional width.

In one or more thirteenth embodiments, further to the ninth through twelfth embodiments, the apparatus further comprises a plurality of second rods or needles extending from each of the plurality of rods or needles, wherein the second rods or needles have a second cross-sectional width of not more than 50% of the cross-sectional width of the plurality of rods or needles.

In one or more fourteenth embodiments, further to the ninth through thirteenth embodiments, the plurality of rods comprise the inorganic dielectric material, the apparatus further comprising a material layer on the plurality of rods, the material layer having an atomic composition of at least ten percent carbon or at least ten percent fluorine.

In one or more fifteenth embodiments, further to the ninth through fourteenth embodiments, the substrate, the IC die, and the one or more structures are part of an IC structure further comprising a structural substrate, and the apparatus or a system comprises a power supply coupled to the IC structure.

In one or more sixteenth embodiments, an apparatus comprises a substrate comprising an interconnect layer, an integrated circuit (IC) die coupled to the interconnect layer of the substrate by a hybrid bond between the IC die and the interconnect layer, and one or more structures laterally adjacent to and extending around an outer perimeter of the hybrid bond, wherein the one or more structures have a contact angle of not less than 150 degrees.

In one or more seventeenth embodiments, further to the sixteenth embodiments, the one or more structures each comprises a plurality of rods or needles having a cross-sectional width of not more than 100 microns.

In one or more eighteenth embodiments, further to the sixteenth or seventeenth embodiments, the plurality of rods or needles each have a long axis substantially orthogonal to a bonding plane of the hybrid bond.

In one or more nineteenth embodiments, further to the sixteenth through eighteenth embodiments, the apparatus further comprises a plurality of second rods or needles extending from each of the plurality of rods or needles, wherein the second rods or needles have a second cross-sectional width of not more than 50% of the cross-sectional width of the plurality of rods or needles.

In one or more twentieth embodiments, further to the sixteenth through nineteenth embodiments, the substrate, the IC die, and the one or more structures are part of an IC structure further comprising a structural substrate, and the apparatus or a system comprises a power supply coupled to the IC structure.

In one or more twenty-first embodiments, a method comprises forming one or more structures around an outer perimeter of a first hybrid bonding region, wherein the one or more structures comprises a plurality of rods having a long axis substantially orthogonal to a bonding plane of the first hybrid bonding region, and wherein the plurality of rods each have a cross-sectional width of not more than 100 microns, evaporating a first liquid droplet between the first hybrid bonding region and a second hybrid bonding region, the first hybrid bonding region of a substrate or an integrated circuit (IC) die and the second hybrid bonding region of the other of the substrate or the IC die, and bonding a first metal pads of the first hybrid bonding region to second metal pads of the second hybrid bonding region.

In one or more twenty-second embodiments, further to the twenty-first embodiments, forming the one or more structures comprises forming a patterned mask over a material layer, etching the material layer to form the one or more structures, and removing the patterned mask.

In one or more twenty-third embodiments, further to the twenty-first or twenty-second embodiments, the method further comprises forming a plurality of second rods extending from each of the plurality of rods, wherein the second rods have a second cross-sectional width of not more than 50% of the cross-sectional width of the plurality of rods, and wherein forming the plurality of second rods comprises growing the plurality of second rods from each of the plurality of rods.

In one or more twenty-fourth embodiments, further to the twenty-first through twenty-third embodiments, the method further comprises forming a material layer on the plurality of rods, the material layer having an atomic composition of at least ten percent carbon or at least ten percent fluorine.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a substrate comprising an interconnect layer;
an integrated circuit (IC) die coupled to the interconnect layer of the substrate by a hybrid bond between the IC die and the interconnect layer; and
one or more structures laterally adjacent to and extending around an outer perimeter of the hybrid bond, wherein the one or more structures comprise a lateral contact surface area that is not more than 50% of a total lateral surface area of the one or more structures.

2. The apparatus of claim 1, wherein the one or more structures comprise a plurality of rods or needles each having an aspect ratio of not less than one.

3. The apparatus of claim 2, wherein the plurality of rods or needles each have a cross-sectional width of not more than 100 microns.

4. The apparatus of claim 3, wherein the plurality of rods or needles have a feature pitch of not less than 150% of the cross-sectional width and not more than 300% of the cross-sectional width.

5. The apparatus of claim 2, further comprising a plurality of second rods or needles extending from each of the plurality of rods or needles, wherein the second rods or needles have a second cross-sectional width of not more than 50% of a cross-sectional width of the plurality of rods or needles.

6. The apparatus of claim 1, wherein the one or more structures comprise material surfaces defining the contact surface area and gaps between the material surfaces defining a remainder of the total surface area.

7. The apparatus of claim 1, wherein the one or more structures comprise an inorganic dielectric material of the hybrid bond, the apparatus further comprising a material layer on the inorganic dielectric material, the material layer having an atomic composition of at least ten percent carbon or at least ten percent fluorine.

8. The apparatus of claim 1, wherein the substrate, the IC die, and the one or more structures are part of an IC structure further comprising a structural substrate, the apparatus further comprising a power supply coupled to the IC structure.

9. An apparatus, comprising:
a substrate comprising an interconnect layer;
an integrated circuit (IC) die coupled to the interconnect layer of the substrate by a hybrid bond that spans a bonding plane between the substrate and the IC die, the bonding plane substantially parallel to a top surface of the substrate, and the hybrid bond comprising composite metal interconnect structures interspersed in an inorganic dielectric material; and
one or more structures laterally adjacent to and extending around an outer perimeter of the inorganic dielectric material, wherein the one or more structures each comprises a plurality of rods or needles having a long axis substantially orthogonal to the bonding plane, and wherein the plurality of rods or needles each have a cross-sectional width of not more than 100 microns.

10. The apparatus of claim 9, wherein the plurality of rods or needles each have a cross-sectional width of not more than 100 nanometers, and wherein the plurality of rods or needles each have an aspect ratio of not less than one.

11. The apparatus of claim 10, wherein the plurality of rods or needles have a feature pitch of not less than 150% of the cross-sectional width and not more than 300% of the cross-sectional width.

12. The apparatus of claim 9, wherein the cross-sectional width of each of the plurality rods or needles is at a location between 10 to 100 nm from a top of each of the plurality rods or needles, and wherein a second cross-sectional width of each of the plurality rods or needles at a location 500 nm from a top of each of the plurality rods is not less than twice the cross-sectional width.

13. The apparatus of claim 9, further comprising a plurality of second rods or needles extending from each of the plurality of rods or needles, wherein the second rods or needles have a second cross-sectional width of not more than 50% of the cross-sectional width of the plurality of rods or needles.

14. The apparatus of claim 9, wherein the plurality of rods comprise the inorganic dielectric material, the apparatus further comprising a material layer on the plurality of rods, the material layer having an atomic composition of at least ten percent carbon or at least ten percent fluorine.

15. The apparatus of claim 9, wherein the substrate, the IC die, and the one or more structures are part of an IC structure further comprising a structural substrate, the apparatus further comprising a power supply coupled to the IC structure.

16. An apparatus, comprising:
a substrate comprising an interconnect layer;
an integrated circuit (IC) die coupled to the interconnect layer of the substrate by a hybrid bond between the IC die and the interconnect layer; and
one or more structures laterally adjacent to and extending around an outer perimeter of the hybrid bond, wherein the one or more structures have a contact angle of not less than 150 degrees.

17. The apparatus of claim 16, wherein the one or more structures each comprises a plurality of rods or needles having a cross-sectional width of not more than 100 microns.

18. The apparatus of claim 17, wherein the plurality of rods or needles each have a long axis substantially orthogonal to a bonding plane of the hybrid bond.

19. The apparatus of claim 17, further comprising a plurality of second rods or needles extending from each of the plurality of rods or needles, wherein the second rods or needles have a second cross-sectional width of not more than 50% of the cross-sectional width of the plurality of rods or needles.

20. The apparatus of claim 11, wherein the substrate, the IC die, and the one or more structures are part of an IC structure further comprising a structural substrate, the apparatus further comprising a power supply coupled to the IC structure.
